(19) United States
(12) Patent Application Publication
(10) Pub. No.: US 2015/0010868 A1
(43) Pub. Date: Jan. 8, 2015

(54) MANUFACTURING METHOD OF LIQUID EJECTION HEAD

(71) Applicant: CANON KABUSHIKI KAISHA, Tokyo (JP)

(72) Inventors: Kenji Fujii, Yokohama-shi (JP); Takanobu Manabe, Kawasaki-shi (JP); Toshiaki Kurosu, Oita-shi (JP); Makoto Watanabe, Yokohama-shi (JP); Yukuo Yamaguchi, Tokyo (JP); Chiaki Muraoka, Kawaguchi-shi (JP); Sayaka Seki, Tokyo (JP)

(21) Appl. No.: 14/384,660

(22) PCT Filed: Feb. 26, 2013
(86) PCT No.: PCT/JP2013/001099

§ 371 Date: Sep. 11, 2014

(30) Foreign Application Priority Data
Mar. 14, 2012 (JP) 2012-057309

(51) Int. Cl. G03F 7/20

(52) U.S. Cl. CPC G03F 7/2022
USPC 430/320

(57) ABSTRACT

A manufacturing method of a liquid ejection head includes a step of performing a first exposure to form a first ejection orifice row and a step of performing a second exposure to form a second ejection orifice row in which ejection orifices are arranged in a row with ejection orifices that form the first ejection orifice row through a connection portion. In an ejection orifice row formed by the first and the second ejection orifice rows, regarding the distances between the centers of ejection orifices in an arrangement direction of the ejection orifices on opening surfaces of the ejection orifices, the ejection orifices are formed so that a distance between the centers of two ejection orifices adjacent to each other with the connection portion in between is longer than a distance between the centers of two ejection orifices adjacent to each other without the connection portion in between.

### TECHNICAL FIELD

The present invention relates to a manufacturing method of a liquid ejection head.

### BACKGROUND ART

A liquid ejection device ejects liquid from a liquid ejection head to a recording medium and records an image and the like. As a manufacturing method of such a liquid ejection head, there is a method described in PTL 1. The manufacturing method of the liquid ejection head described in PTL 1 will be briefly described. First, an element substrate including an energy generating element that generates energy used to eject liquid from an ejection orifice is prepared. Next, a positive-type photosensitive resin layer including optical absorption agent is formed on the element substrate. Then, the positive-type photosensitive resin layer is exposed and a pattern including a shape of flow path is formed. Next, a negative-type photosensitive resin layer, which will be an ejection orifice forming member, is formed so that the negative-type photosensitive resin layer covers the pattern. The negative-type photosensitive resin layer is exposed to i-line (wavelength is 365 nm) and an ejection orifice row is formed in which ejection orifices are disposed in a row in an arrangement direction. Finally, the pattern is removed and a flow path of liquid is formed.

When an ejection orifice row is formed in a liquid ejection head by the method of PTL 1, there is a case in which a pattern larger than a field angle size, which is an area that can be exposed by an exposure apparatus, is required to be exposed. In this case, as described in PTL 2, a manufacturing method called “fractionated exposure” may be used. The fractionated exposure is a method in which a pattern which cannot be located within the field angle is divided on a mask so that the pattern is located within the field angle and the pattern is exposed. In other words, exposure is performed using a mask including a plurality of ejection orifice row patterns and a plurality of ejection orifice rows formed by the plurality of ejection orifice row patterns are connected by a connection portion, so that one ejection orifice row is formed in one element substrate. Normally, the connection portion is arranged at a position that divides the ejection orifice row in the arrangement direction (longitudinal direction).

### CITATION LIST

### Patent Literature

PTL 1: Japanese Patent Laid-Open No. 2009-166492

PTL 2: Japanese Patent Laid-Open No. 2003-145769

### SUMMARY OF INVENTION

The present invention provides a manufacturing method of a liquid ejection head including a step of performing a first exposure on a photosensitive resin layer and forming a first ejection orifice row in the photosensitive resin layer and a step of performing a second exposure on the photosensitive resin layer and forming a second ejection orifice row in which ejection orifices are arranged in a row with ejection orifices that form the first ejection orifice row through a connection portion in the photosensitive resin layer. In an ejection orifice row formed by the first ejection orifice row and the second ejection orifice row, regarding the distances between the centers of ejection orifices in an arrangement direction of the ejection orifices on opening surfaces of the ejection orifices, the ejection orifices are formed so that a distance between the centers of two ejection orifices adjacent to each other with the connection portion in between is longer than a distance between the centers of two ejection orifices adjacent to each other without the connection portion in between.

Further features of the present invention will become apparent from the following description of an exemplary embodiment with reference to the attached drawings.

### BRIEF DESCRIPTION OF DRAWINGS

FIG. 1 is a schematic diagram of a liquid ejection head.

FIG. 2 is a diagram showing an exposure apparatus.

FIG. 3 is a schematic cross-sectional view showing an inclination of a light flux in an exposure of a reduced size projection method.

FIG. 4 is a schematic diagram showing a landing position of liquid.

FIG. 5 is a schematic diagram of a mask having an ejection orifice row pattern.

FIG. 6A is a schematic diagram showing a fractionated exposure.

FIG. 6B is a schematic diagram showing a fractionated exposure.

FIG. 7 is a schematic cross-sectional view of a liquid ejection head manufactured by a conventional method.

FIG. 8 is a schematic cross-sectional view showing an example of a liquid ejection head manufactured by the present invention.

FIG. 9 is a schematic cross-sectional view showing an example of a liquid ejection head manufactured by the present invention.

### DESCRIPTION OF EMBODIMENT

According to the study of the inventors, it is observed that landing positions of droplets ejected from ejection orifices adjacent to each other with a connection portion in between are shifted from each other, and a streak occurs on a recording medium. Landed dots come close to each other and the dots come into contact with each other, so that the streak occurs.

Present invention prevents a streak from occurring on a recording medium when ejecting liquid to the recording medium by using a liquid ejection head having an ejection orifice row formed by the fractionated exposure.

Hereinafter, an embodiment of the present invention will be described with reference to the drawings. In the description below, components having the same function are given the same reference numerals in the drawings and the description thereof may be omitted.

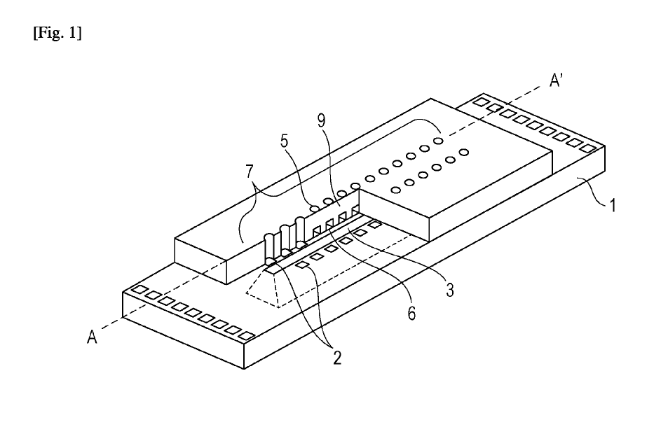

FIG. 1 is a schematic diagram showing an example of a liquid ejection head manufactured by a manufacturing method of a liquid ejection head of the present invention. The liquid ejection head includes an element substrate 1 including energy generating elements 2. Although the energy generating elements 2 are directly disposed on the element substrate 1 in FIG. 1, the energy generating elements 2 may be floating in the air with respect to the element substrate 1. The energy generating elements 2 are arranged in two rows at a predetermined pitch. As the element substrate 1, for example, a substrate formed of silicon is used. The element substrate 1 includes a supply port 3 that supplies liquid to flow paths 6 and ejection orifices 5. An ejection orifice forming member 9 that forms the ejection orifices 5 is formed on the element substrate 1. A plurality of ejection orifices 5 are collectively formed into one ejection orifice row 7. The ejection orifices 5 are arranged in an arrangement direction to be the ejection orifice row 7. The arrangement direction of the ejection orifices 5 is a direction indicated by an A-A′ line in FIG. 1. In FIG. 1, two ejection orifice rows 7 are formed. The supply port 3 is connected to the ejection orifices 5 through the flow paths 6. The ejection orifice forming member 9 is also a flow path forming member that forms the flow paths 6. In the form of FIG. 1, the ejection orifice 5 and the energy generating element 2 face each other and energy generated by the energy generating element 2 is applied to liquid (ink) that fills the flow path 6 through the supply port 3. Thereby, a droplet is ejected from the ejection orifice 5.

An example of the manufacturing method of the liquid ejection head shown in FIG. 1 will be described. First, the element substrate 1 including the energy generating elements 2 is prepared. Next, a positive-type photosensitive resin layer is formed on the element substrate 1 and the positive-type photosensitive resin layer is patterned by photolithography, so that a flow path pattern (a form of flow paths) to be the flow paths 6 is formed. A negative-type photosensitive resin to be the ejection orifice forming member 9 is coated on the element substrate 1 on which the flow path pattern is formed, and a negative-type photosensitive resin layer is formed. Next, the coated negative-type photosensitive resin layer is exposed by using a mask. After the exposure, a pre-bake and a development process are performed to form the ejection orifices 5. Further, the supply port 3 is formed by anisotropic etching or the like, and then the flow path pattern is removed to form the flow paths 6. Finally, chips of the liquid ejection head are cut from a wafer and the liquid ejection head is electrically connected to contact pads of the element substrate 1.

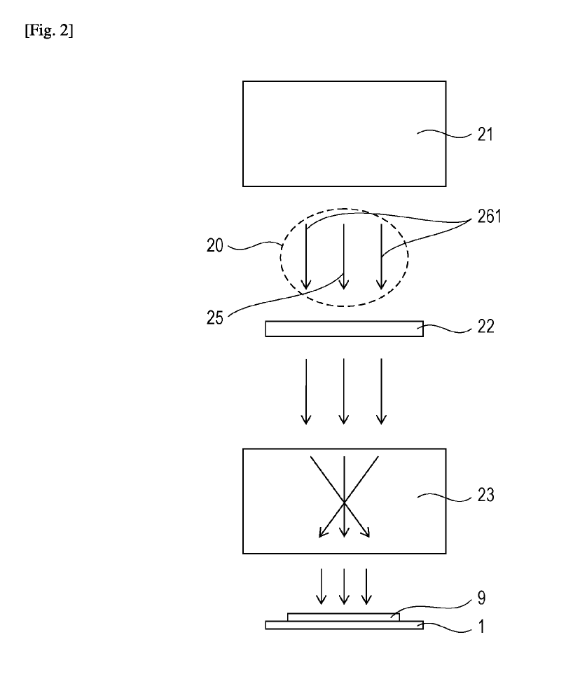

Next, the exposure to form the ejection orifices will be described in further detail. The exposure is performed by using, for example, an exposure apparatus as shown in FIG. 2. Irradiation of a light beam from a light source 21 is performed by using, for example, i-line of a light beam radiated from a high pressure mercury vapor lamp. The light beam used for the exposure is not limited to this, but any light beam having a wavelength to which the member to be patterned is sensitive can be used. The exposure apparatus includes a reduction projection optical system 23 and exposes the ejection orifice forming member 9 which is the negative-type photosensitive resin layer on the element substrate 1.

When the exposure is performed, the light beam may be inclined with respect to an optical axis of an optical system. The inclination of the light beam with respect to the optical axis of the optical system is called a telecentric phenomenon. The degree of the inclination is called an off-axis telecentric degree. In particular, the telecentric phenomenon occurs in a reduction projection optical system.

An absolute value of the off-axis telecentric degree of an outer light beam 261 of a light beam flux 20 tends to be greater than that of a light beam 25 at the center of the light beam flux 20. The center of the light beam flux means a center of gravity of the light beam flux on a cross-section of the light beam flux in a direction in parallel with a mask 22. When the center of the light beam flux and the center of the mask correspond to each other (are coaxially arranged), the absolute value of the off-axis telecentric degree of the outer light beam 261, that is, a light beam passing through near the edge of the mask, is greater than that of the light beam 25 passing through the center of the mask. The centers of the mask and the lens basically correspond to each other, so that the same goes for the relationship with the lens. Due to the effect of the telecentric phenomenon, the light beam irradiated from the light source to the mask is inclined with respect to a surface perpendicular to the surface of the ejection orifice forming member 9. When an inclination angle of the light beam is X, the change of the image forming position by a distortion made by defocusing by 1 micrometer is represented by “1000*tan X (nm)”. In a case of a normal nozzle chip, the change of the image forming position is of the order of nm. Therefore, the inclination angle X is a very small value, so that it is approximately equal with “tan X” and “sin X”.

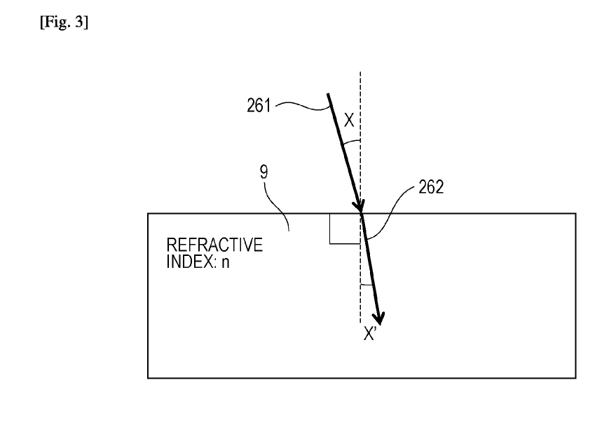

As shown in FIG. 3, the outer light beam 261 with an inclination angle X is irradiated to the ejection orifice forming member 9 on the element substrate, an inclination angle X′ of the ejection orifice to be patterned is approximately equal with “X/n” when the refractive index of a photosensitive resin which is the ejection orifice forming member is n and the refractive index of the air is 1.

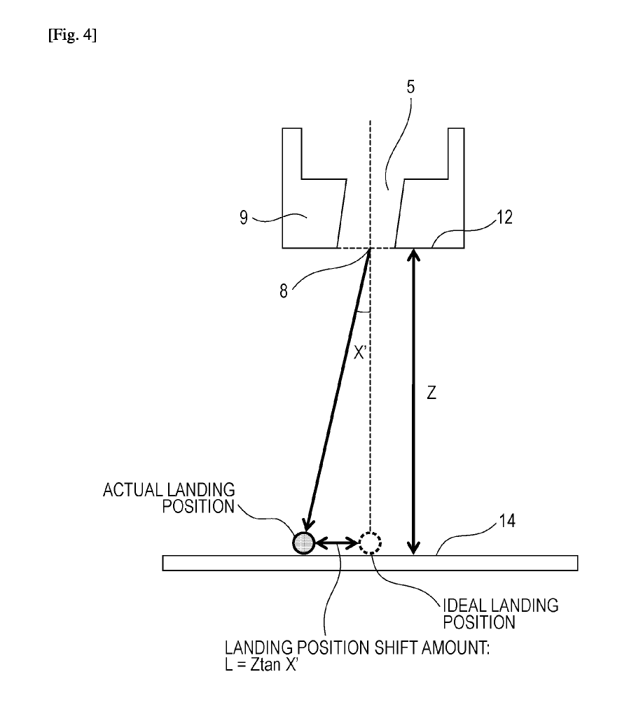

As shown in FIG. 4, a droplet ejected from the ejection orifice 5 formed by the light beam 262 having the inclination angle X′ is ejected with the inclination angle X′ with respect to a perpendicular line connected from the center 8 of the ejection orifice to the recording medium, that is, a line perpendicular to an opening surface 12 of the ejection orifice. Therefore, when the droplet lands on the recording medium 14, the droplet lands at a position shifted from an ideal landing position. When a distance from the opening surface 12 of the ejection orifice to the recording medium is Z, the landing position shift amount L is represented by “L=Ztan X′”.

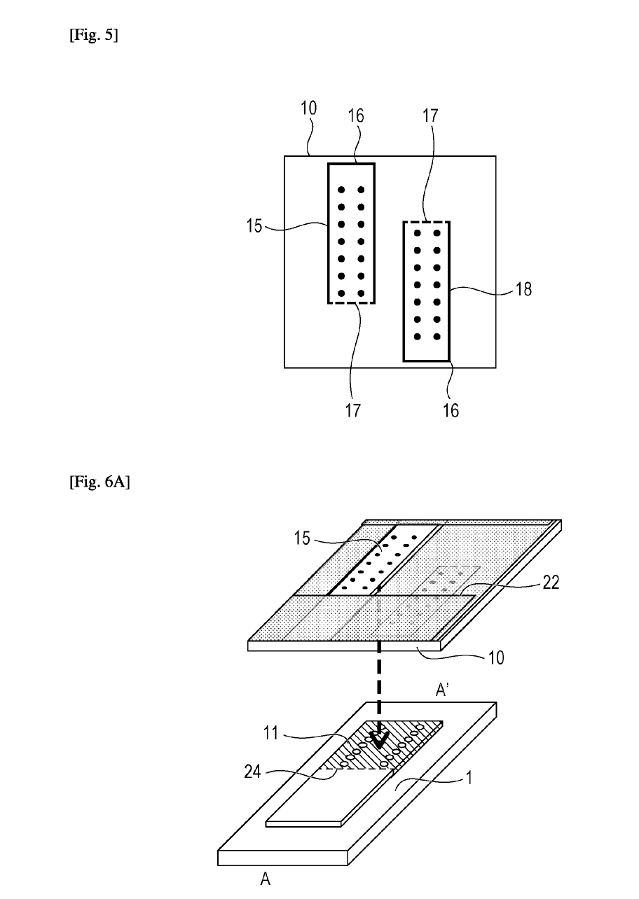

Here, it is assumed that an exposure is performed by using a mask 10 having a plurality of ejection orifice row patterns as shown in FIG. 5 and one ejection orifice row is formed. The one ejection orifice row is formed by connecting a plurality of ejection orifice rows formed by a plurality of ejection orifice row patterns 15 and 18 by a connection portion. In other words, one ejection orifice row is formed by the fractionated exposure. In the plurality of ejection orifice rows, the ejection orifices forming each ejection orifice row are arranged in a row through the connection portion. Also on the mask, there is a portion 17 to be a connection portion. Of course, not only one row, but also a plurality of rows may be formed at the same time by the fractionated exposure.

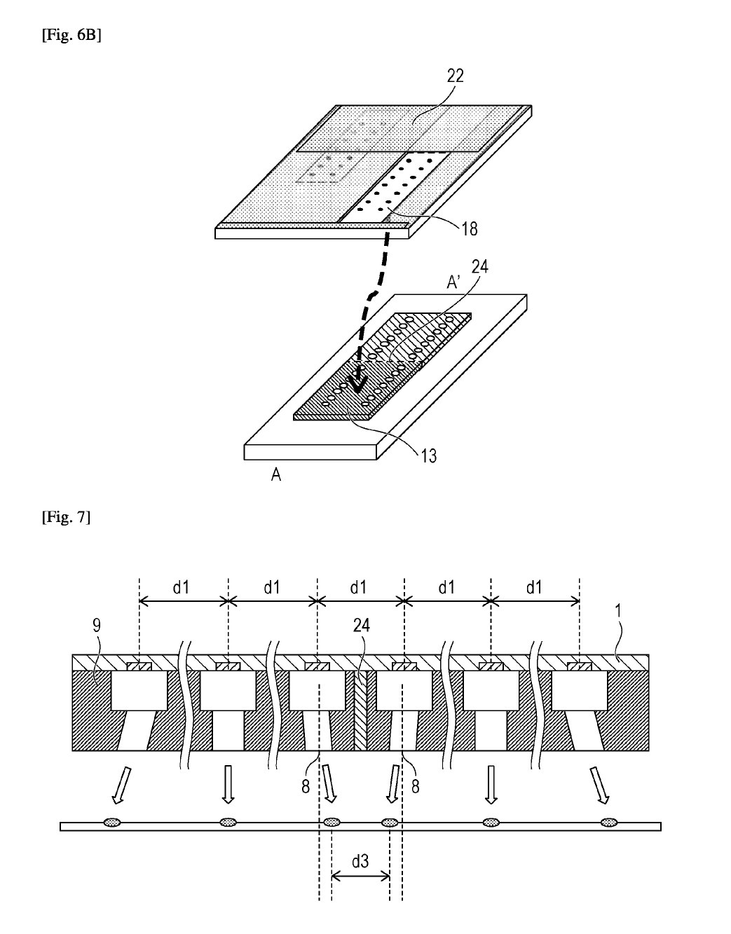

FIGS. 6A and 6B show a situation of the fractionated exposure. FIG. 6A shows a situation in which a first time exposure (first exposure) is performed on the photosensitive resin layer by using the ejection orifice row pattern 15 of a plurality of ejection orifice row patterns included in the mask 10. By the first exposure, an upper half 11 (first ejection orifice row) of one ejection orifice row is formed. In FIGS. 6A and 6B, an upper half of two ejection orifice rows is formed at the same time. Here, the other ejection orifice row pattern 18 is light-shielded by a method such as closing a shutter 22 of the exposure apparatus. Therefore, the pattern in this portion is not exposed. Next, as shown in FIG. 6B, a second exposure is performed on the photosensitive resin layer. In the second exposure, a lower half 13 (second ejection orifice row) of the one ejection orifice row is formed so that the ejection orifices are arranged in a row with the upper half 11 (first ejection orifice row) of the one ejection orifice row formed previously through a connection portion 24. Here, the other ejection orifice row pattern 15 is light-shielded by a method such as closing a shutter 22 of the exposure apparatus. The connection portion is a portion in which a plurality of ejection orifice rows are connected so that the ejection orifices are arranged in a row. When a plurality of ejection orifice rows are connected in the connection portion, one ejection orifice row as shown in FIG. 6B is formed. Here, one ejection orifice row is formed from the first ejection orifice row and the second ejection orifice row.

When the fractionated exposure as described above is performed, since one row of an ejection orifice row pattern cannot be located within the field angle, it is conceivable that the ejection orifice row pattern is arranged as shown in FIG. 5. Specifically, the portion 17 to be a connection portion corresponding to the connection portion 24 is located at a position a little away from the center of the mask and an end portion 16 of the ejection orifice row pattern is located away from the center of the mask in a direction opposite to the connection portion pattern 17. The inventors found that, in such an arrangement, in particular when the exposure is a reduction projection optical system, an ejection orifice row as shown in FIG. 7 is formed due to the effect of the off-axis telecentric degree described above. Specifically, in each ejection orifice row which is formed by dividing a pattern, the ejection orifice is formed to be inclined outward. As shown in FIG. 7, when seeing the ejection orifice rows as one whole ejection orifice row, the ejection orifices which overlap the connection portion 24 are formed to be inclined inward. In other words, the two ejection orifices adjacent to each other with the connection portion in between incline in a direction in which the ejection orifices come closer each other in a direction from the energy generating element to the opening surface of the ejection orifice. In FIG. 7, the pitch (d1) of the energy generating elements is constant. However, the distance between the centers 8 of ejection orifices adjacent to each other is not constant. The distance between the centers of the two ejection orifices adjacent to each other with the connection portion 24 in between is shorter than the distance between the centers of two ejection orifices adjacent to each other without the connection portion in between. Therefore, the distance d3 between landing positions of liquid ejected from these ejection orifices and lands on a recording medium is shorter than d1, and further, shorter than a distance between landing positions of other liquid. As a result, landed dots come close to each other and a streak may occur on the recording medium.

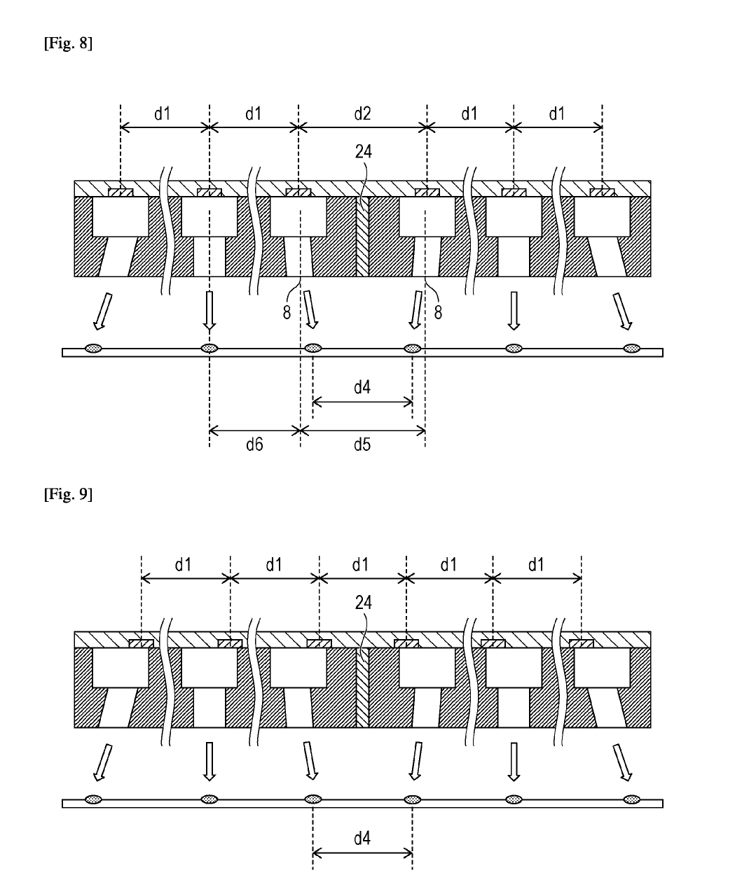

By considering this mechanism, in the present invention, as shown in FIG. 8, the ejection orifices are formed so that the distance d5 between the centers of the two ejection orifices adjacent to each other with the connection portion 24 in between is longer than a distance (for example, d6) between the centers of two ejection orifices adjacent to each other without the connection portion 24 in between. In other words, regarding the distances between the centers of ejection orifices in the arrangement direction of the ejection orifices on the opening surfaces of the ejection orifices, the ejection orifices are formed so that the distance between the centers of the two ejection orifices adjacent to each other with the connection portion in between is longer than a distance between the centers of two ejection orifices adjacent to each other without the connection portion in between. For example, as shown in FIG. 8, the connection portion 24 has a measurable width. Only the connection portion may be exposed by using another mask or the ejection orifice row pattern is arranged so that the distance between the connection portion and the ejection orifice adjacent to the connection portion is increased. As a result, the landing position distance d4 of the liquid can be longer than the distance d3 shown in FIG. 7, so that it is possible to reliably prevent the streak from occurring on a recording medium. At least, it is preferable that the distance between the centers of the two ejection orifices adjacent to each other with the connection portion in between is longer than a distance which is between the centers of two ejection orifices adjacent to each other and which is adjacent to the above distance. Also, it is preferable that the distance between the centers of the two ejection orifices adjacent to each other with the connection portion in between is longer than or equal to 1.1 times the maximum distance between the centers of two ejection orifices adjacent to each other without the connection portion in between and shorter than or equal to 2.0 times the maximum distance. Further, it is preferable that the distance between the centers of the two ejection orifices adjacent to each other with the connection portion in between is longer than any one of the distances between the centers of two ejection orifices adjacent to each other without the connection portion in between. It is more preferable that it is designed so that all the distances between landing positions of liquid ejected from a certain ejection orifice and an ejection orifice adjacent to the certain ejection orifice are the same in one ejection orifice row.

The center of the ejection orifice in the present invention is the center of gravity of a cross-sectional shape of the ejection orifice. When the cross-sectional shape of the ejection orifice is a circle, the center of the ejection orifice is the center of the circle.

When the liquid ejection head has a plurality of ejection orifice rows, at least in one ejection orifice row, regarding the distances between the centers of ejection orifices in the arrangement direction of the ejection orifices, the ejection orifices are formed so that the distance between the centers of the two ejection orifices adjacent to each other with the connection portion in between is longer than a distance between the centers of two ejection orifices adjacent to each other without the connection portion in between. In all the ejection orifice rows included in the liquid ejection head, it is preferable that the ejection orifice rows have the above relationship.

According to the manufacturing method of the liquid ejection head of the present invention, a landing position of liquid ejected from an ejection orifice located at the end portion tends to be outer than usual. However, the landing position of liquid ejected from an ejection orifice located at the end portion can be easily controlled by, for example, adjusting the conveying pitch of a recording medium.

### EXAMPLES

### Example 1

As an exposure apparatus of the reduction projection optical system, FPA-3000i5 (manufactured by CANON KABUSHIKI KAISHA) or the like is used. The negative-type photosensitive resin layer is exposed by the method shown in FIGS. 6A and 6B and the liquid ejection head shown in FIG. 8 is manufactured. The ejection orifices are formed so that the distance between the centers of the two ejection orifices adjacent to each other with the connection portion in between is 72.5 micrometers, which is longer than a distance between the centers of two ejection orifices adjacent to each other without the connection portion in between. As a result, the distance between the centers of the two ejection orifices adjacent to each other with the connection portion in between is the maximum among the distances between the centers of two ejection orifices adjacent to each other. Regarding the pitch of the energy generating elements, the pitch d2 with the connection portion in between is formed to be longer than the pitch d1 without the connection portion in between.

An image is recorded on a recording medium by using the liquid ejection head manufactured in this way. When the recorded image is observed visually, the occurrence of streak is hardly observed.

### Example 2

Although the example 1 has one connection portion, the present example has two connection portions. Specifically, the present example is formed by a fractionated exposure method which divides one ejection orifice row into three portions. The ejection orifices are formed so that each of the distances between the centers of the two ejection orifices adjacent to each other with the connection portion in between is 57.5 micrometers, which is longer than a distance between the centers of two ejection orifices adjacent to each other without the connection portion in between. Since there are three ejection orifice row patterns in the present example, the pattern to be the connection portion can come much closer to the center of the mask compared with the example 1. Therefore, it is possible to further suppress the effect of the off-axis telecentric degree.

An image is recorded on a recording medium by using the liquid ejection head manufactured in this way. When the recorded image is observed visually, the occurrence of streak is hardly observed.

### Example 3

Although the pitch of the energy generating elements is changed in the example 1, as shown in FIG. 9, the pitch d1 of the energy generating elements is constant in the present example. By doing so, a conventional element substrate can be used without change. Other than the above, the liquid ejection head is manufactured in the same manner as in the example 1.

An image is recorded on a recording medium by using the liquid ejection head manufactured in this way. When the recorded image is observed visually, the occurrence of streak is hardly observed.

According to the present invention, it is possible to prevent a streak from occurring on a recording medium even when ejecting liquid to the recording medium by using a liquid ejection head having an ejection orifice row formed by the fractionated exposure.

While the present invention has been described with reference to an exemplary embodiment, it is to be understood that the invention is not limited to the disclosed exemplary embodiment. The scope of the following claims is to be accorded the broadest interpretation so as to encompass all such modifications and equivalent structures and functions.

This application claims the benefit of Japanese Patent Application No. 2012-057309, filed Mar. 14, 2012, which is hereby incorporated by reference herein in its entirety.

1. A manufacturing method of a liquid ejection head, comprising:
a step of performing a first exposure on a photosensitive resin layer and forming a first ejection orifice row in the photosensitive resin layer; and
a step of performing a second exposure on the photosensitive resin layer and forming a second ejection orifice row in which ejection orifices are arranged in a row with ejection orifices that form the first ejection orifice row through a connection portion in the photosensitive resin layer;
wherein, in an ejection orifice row formed by the first ejection orifice row and the second ejection orifice row, regarding the distances between the centers of ejection orifices in an arrangement direction of the ejection orifices on opening surfaces of the ejection orifices, the ejection orifices are formed so that a distance between the centers of two ejection orifices adjacent to each other with the connection portion in between is longer than a distance between the centers of two ejection orifices adjacent to each other without the connection portion in between.

2. The manufacturing method of a liquid ejection head according to claim 1, wherein the first exposure and the second exposure are an exposure performed by a reduction projection optical system.

3. The manufacturing method of a liquid ejection head according to claim 1, wherein the distance between the centers of the two ejection orifices adjacent to each other with the connection portion in between is longer than any one of distances between the centers of two ejection orifices adjacent to each other without the connection portion in between.

4. The manufacturing method of a liquid ejection head according to claim 1, wherein, in all ejection orifice rows included in the liquid ejection head, regarding the distances between the centers of ejection orifices in an arrangement direction of the ejection orifices on opening surfaces of the ejection orifices, the ejection orifices are formed so that the distance between the centers of two ejection orifices adjacent to each other with the connection portion in between is longer than a distance between the centers of two ejection orifices adjacent to each other without the connection portion in between.

5. The manufacturing method of a liquid ejection head according to claim 1, wherein the photosensitive resin layer is a negative-type photosensitive resin layer.

6. The manufacturing method of a liquid ejection head according to claim 1, wherein the two ejection orifices adjacent to each other with the connection portion in between incline with respect to an opening surface of an ejection orifice of the photosensitive resin layer.

7. The manufacturing method of a liquid ejection head according to claim 6, wherein the liquid ejection head has energy generating elements and the two ejection orifices adjacent to each other with the connection portion in between incline in a direction in which the ejection orifices come closer each other in a direction from the energy generating element to the opening surface of the ejection orifice.
